(19) United States
(12) Patent Application Publication
(10) Pub. No.: US 2022/0189911 A1
(43) Pub. Date: Jun. 16, 2022

(54) AUTOMATED-POSITION-ALIGNING METHOD FOR TRANSFERRING CHIP AND SYSTEM USING THE METHOD

(71) Applicant: Yu-Jung WU, Zhubei (TW)

(72) Inventors: Yu-Jung WU, Zhubei (TW); Hsu-Nan FANG, Zhubei (TW)

(21) Appl. No.: 17/321,389

(22) Filed: May 14, 2021

(30) Foreign Application Priority Data
Dec. 11, 2020 (TW) 109143742

(51) Int. Cl. H01L 23/00; H01L 21/673; B65G 47/90

(52) U.S. Cl. CPC H01L 24/95; H01L 21/67336; H01L 2224/95085; H01L 2224/95146; B65G 47/90

(57) ABSTRACT

An automated-position-aligning method for transferring chips includes forming a chip-carrier base, applying a liquid, disposing a chip, transporting a carrier substrate and transferring the chip. A related system includes a carrier substrate, a liquid applying device, a chip disposing device, a carrier substrate transporting device and a chip transferring device. A carrier surface of the carrier substrate is crisscrossed by spacing grooves to form chip-carrier bases thereon. The carrier surface is hydrophilic, and the spacing grooves are hydrophobic. The liquid gathers on the chip-carrier bases. A plurality of chips are positioned and attached on the respective chip-carrier bases by surface free energy of the liquid. An electromagnetic wave radiates to the carrier substrate to heat and evaporate the liquid between each chip-carrier base and each chip such that the chips are released from the chip-carrier bases and fall to a receiving surface of a receiving substrate.

### FIELD OF THE INVENTION

The present invention relates to a chip transferring method and system thereof, and more particularly relates to an automated-position-aligning method for transferring chip and system using the method that uses liquid to attach chips to perform chip transportation.

### BACKGROUND OF THE INVENTION

In manufacturing processes of an electronic device that require to massively transfer chips on a substrate, it is well-known that a process of laser lift-off is applied. Specifically, the process of laser lift-off is a process that irradiate laser beam on a sacrificial layer, or called dynamic release layer, i.e., DRL to heat up the sacrificial layer to form a tiny explosion so as to generate a pushing force to move the chips to the substrate.

However, the process of laser lift-off in the conventional technique can only be implemented by using a sacrificial layer containing specific chemical materials. The sacrificial layer containing specific chemical materials is expensive, which causes cost increase for the electronic devices manufacture. Moreover, the heating process for forming the tiny explosion will cause the sacrificial layer to be a chemical irreversible material on, which will cause the sacrificial layer becoming a non-recycle material. Consequently, the sacrificial layer as a result becomes regulated chemical waste and may bring hidden worries for environmental protection.

### SUMMARY OF THE INVENTION

Accordingly, one objective of the present invention is to provide an automated-position-aligning method for transferring chip and system using the method, which can achieve environmental protection and reduce the manufacturing cost.

In order to achieve the above objective, the present invention provides an automated-position-aligning method for transferring chip, comprising: a chip-carrier base forming step of forming a plurality of spacing grooves on a carrier surface of a carrier substrate, wherein the carrier surface is hydrophilic, all the spacing grooves are hydrophobic trenches, and the carrier surface is crisscrossed by the plurality of spacing grooves to form a plurality of chip-carrier bases thereon, each of which is surrounded by the spacing grooves intersecting with each other; a liquid applying step of applying liquid on the carrier surface of the carrier substrate such that the liquid is gathered on the respective chip-carrier bases while being repelled by the plurality of spacing grooves; a chip disposing step of respectively disposing a plurality of chips onto the plurality of chip-carrier bases with the liquid gathered on each chip-carrier base being sandwiched between each chip-carrier base and each chip such that the chips are positioned and attached on the respective chip-carrier bases by surface free energy of the liquid; a carrier substrate transporting step of transporting the carrier substrate on which the plurality of chips are being positioned and attached to a position where the carrier surface of carrier substrate faces toward a receiving surface of a receiving substrate; and a chip transferring step of radiating an electromagnetic wave to the carrier substrate so as to heat and evaporate the liquid between each chip-carrier base and each chip such that the chips are released from the chip-carrier bases and fall down to the receiving surface of the receiving substrate.

In one embodiment of the present invention, the automated-position-aligning method for transferring chip is provided, wherein a plurality of chip-receiving bases are formed on the receiving surface of the receiving substrate, and in the carrier substrate transporting step, the carrier surface of carrier substrate faces toward the receiving surface of the receiving substrate in a manner that the chip-carrier bases respectively correspond to the chip-receiving bases on the receiving surface.

In one embodiment of the present invention, the automated-position-aligning method for transferring chip is provided, wherein in the chip-carrier base forming step, the carrier surface is subjected to a smoothing process to become hydrophilic, and the spacing groove is subjected to a roughening process to become hydrophobic.

In one embodiment of the present invention, the automated-position-aligning method for transferring chip is provided, wherein in the chip-carrier base forming step, the carrier substrate is a substrate made of glass transparent to the electromagnetic wave radiated in the chip transferring step to enable the liquid between each chip-carrier base and each chip to be radiated by the electromagnetic wave.

In one embodiment of the present invention, the automated-position-aligning method for transferring chip is provided, wherein in the liquid applying step, the liquid applied on the carrier surface of the carrier substrate is water which is evaporable by the electromagnetic wave applied in the chip transferring step.

In one embodiment of the present invention, the automated-position-aligning method for transferring chip is provided, wherein in the chip transferring step, the electromagnetic wave radiated to the carrier substrate is a laser beam.

In one embodiment of the present invention, the automated-position-aligning method for transferring chip is provided, wherein in the chip-carrier base forming step, the plurality of spacing grooves are a plurality of longitudinal trenches arranged at lateral intervals from each other, and a plurality of lateral trenches arranged at longitudinal intervals from each other, and the plurality of longitudinal trenches intersect the plurality of lateral trenches to form the plurality of chip-carrier bases in a checkerboard distribution.

In order to achieve the above objective, the present invention provides a system using an automated-position-aligning method for transferring chip, comprising: a carrier substrate having a carrier surface and a plurality of spacing grooves, wherein the carrier surface is hydrophilic, all the spacing grooves are hydrophobic trenches, and the carrier surface is crisscrossed by the plurality of spacing grooves formed thereon to form a plurality of chip-carrier bases, each of which is surrounded by the spacing grooves intersecting with each other on the carrier surface; a liquid applying device provided with a nozzle disposed corresponding to the carrier surface of the carrier substrate and configured to apply liquid on the carrier surface of the carrier substrate such that the liquid is gathered on the respective chip-carrier bases while is repelled by the plurality of spacing grooves; a chip disposing device arranged corresponding to the carrier substrate and configured to dispose a plurality of chips onto the plurality of chip-carrier bases with the liquid gathered on each chip-carrier base being sandwiched between each chip-carrier base and each chip such that the chips are positioned and attached on the respective chip-carrier bases by surface free energy of the liquid; a carrier substrate transporting device arranged corresponding to the carrier substrate and configured to transport the carrier substrate on which the plurality of chips are being positioned and attached to a position where the carrier surface of carrier substrate faces toward a receiving surface of a receiving substrate; and a chip transferring device arranged corresponding to the carrier substrate transporting device and configured to radiate an electromagnetic wave to the carrier substrate so as to heat and evaporate the liquid between the plurality of chip-carrier bases and the plurality of chips such that the chips are released from the chip-carrier bases and fall down to the receiving surface of the receiving substrate.

In one embodiment of the present invention, the system using the automated-position-aligning method for transferring chip is provided, wherein in the carrier substrate, the plurality of spacing grooves are a plurality of longitudinal trenches arranged at lateral intervals from each other and a plurality of lateral trenches arranged at longitudinal intervals from each other, and the plurality of longitudinal trenches intersect the plurality of lateral trenches to form the plurality of chip-carrier bases in a checkerboard distribution.

In one embodiment of the present invention, the system using the automated-position-aligning method for transferring chip is provided, wherein the electromagnetic wave radiated by the chip transferring device is a laser beam.

The automated-position-aligning method for transferring chip of the present invention has the technical effects as follows. The surface free energy of the liquid is applied to effectively enable chips to positional aligning on the respective chip-carrier bases. Moreover, compared to the usage of sacrificial layer, the used of liquid in the process of laser lift-off could greatly reduce the cost for electronic devices manufacture and solve the possible environment pollution.

### BRIEF DESCRIPTION OF THE DRAWINGS

FIG. 1 is a schematic flow chart of an automated-position-aligning method for transferring chip according to an embodiment of the present invention;

FIG. 2 is a schematic drawing illustrating a system using an automated-position-aligning method for transferring chip according to an embodiment of the present invention;

FIG. 3 is a schematic top view of a carrier substrate of the system using the automated-position-aligning method for transferring chip according to the embodiment of the present invention;

FIG. 4 is a schematic partial enlarged side view of the carrier substrate of the system using the automated-position-aligning method for transferring chip according to the embodiment of the present invention;

FIG. 5 is another schematic partial enlarged side view of the carrier substrate of the system using the automated-position-aligning method for transferring chip according to the embodiment of the present invention; and

FIG. 6 is a schematic drawing illustrating a chip transferring step performed by the system using the automated-position-aligning method for transferring chip according to the embodiment of the present invention.

### DETAILED DESCRIPTION OF THE PREFERRED EMBODIMENTS

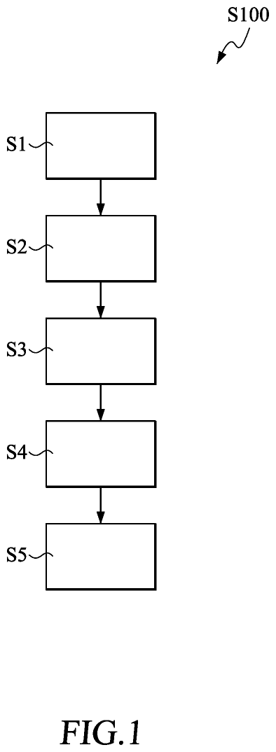

The preferred embodiments of the present invention are described in detail with reference to FIGS. 1 to 6. The description is used for explaining the embodiments of the present invention only, but not for limiting the scope of the claims.

As shown in FIG. 1, an automated-position-aligning method S100 for transferring chip according to one embodiment of the present invention, comprises: a chip-carrier base forming step S1, a liquid applying step S2, a chip disposing step S3, a carrier substrate transporting step S4 and a chip transferring step S5. By the method, in the present invention, the surface free energy of the liquid is applied to effectively enable chips to positional aligning on the respective chip-carrier bases. Furthermore, in the present invention, compared to the usage of sacrificial layer, the used of liquid in the process of laser lift-off could greatly reduce the cost for electronic devices manufacture and solve the possible environment pollution.

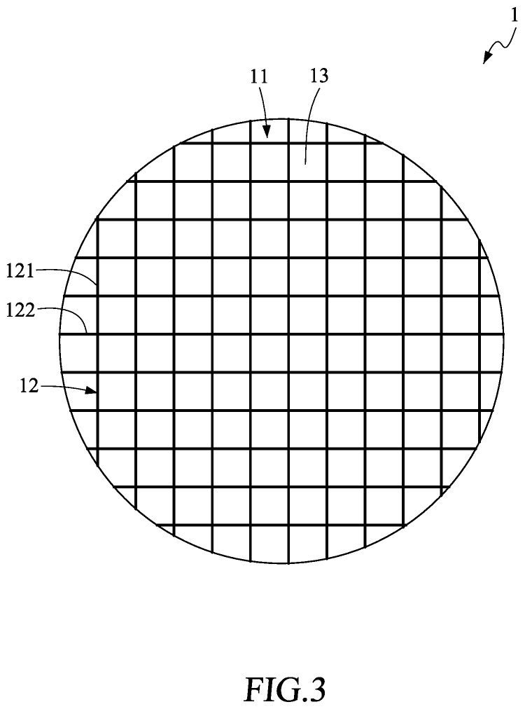

In the chip-carrier base forming step S1, shown in FIG. 1, of the present invention, in FIG. 3, a plurality of spacing grooves 12 are formed on a carrier surface 11 of a carrier substrate 11. The carrier surface 11 is hydrophilic, and all the spacing grooves 12 are hydrophobic trenches. Furthermore, the carrier surface 11 is crisscrossed by the plurality of spacing grooves 12 to form a plurality of chip-carrier bases 13 thereon, each of which is surrounded by the spacing grooves 12 intersecting with each other. Moreover, the carrier surface 11 is hydrophilic to a predetermined working liquid, such as water, and the spacing grooves 12 are hydrophobic to the predetermined working liquid.

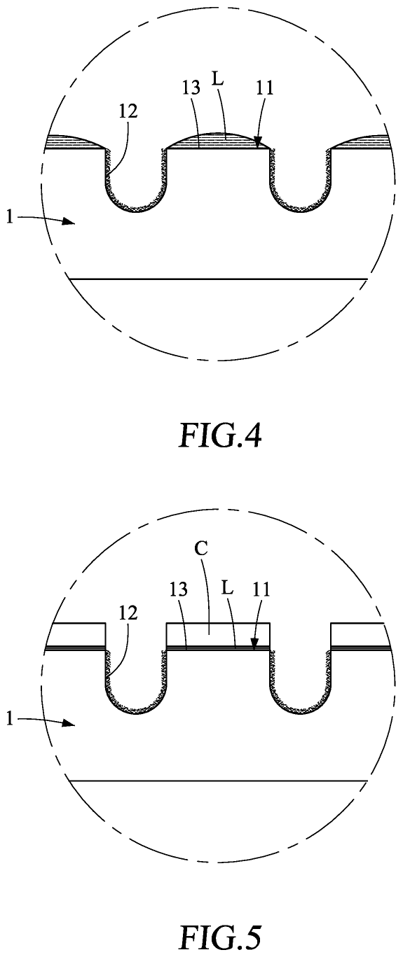

The detail is shown in FIGS. 4 5. In the chip-carrier base forming step S1, shown in FIG. 1, of the automated-position-aligning method S100 for transferring chip according to the embodiment of the present invention, in FIG. 5, the carrier surface 11 is subjected to a smoothing process to become hydrophilic, and the spacing groove 12 is subjected to a roughening process to become hydrophobic. However, the present invention is not limited to this, a physical or chemical coating process may be used to modify the carrier surface 11 and the spacing groove 12 to be hydrophilic and hydrophobic respectively.

For example, in the chip-carrier base forming step S1 of the automated-position-aligning method S100, as shown in FIG. 1, for transferring chip according to the embodiment of the present invention, in FIG. 3, the plurality of spacing grooves 12 are a plurality of longitudinal trenches 121 arranged at lateral intervals from each other, and a plurality of lateral trenches 122 arranged at longitudinal intervals from each other. Moreover, the plurality of longitudinal trenches 121 intersect the plurality of lateral trenches 122 to form the plurality of chip-carrier bases 13 in a checkerboard distribution.

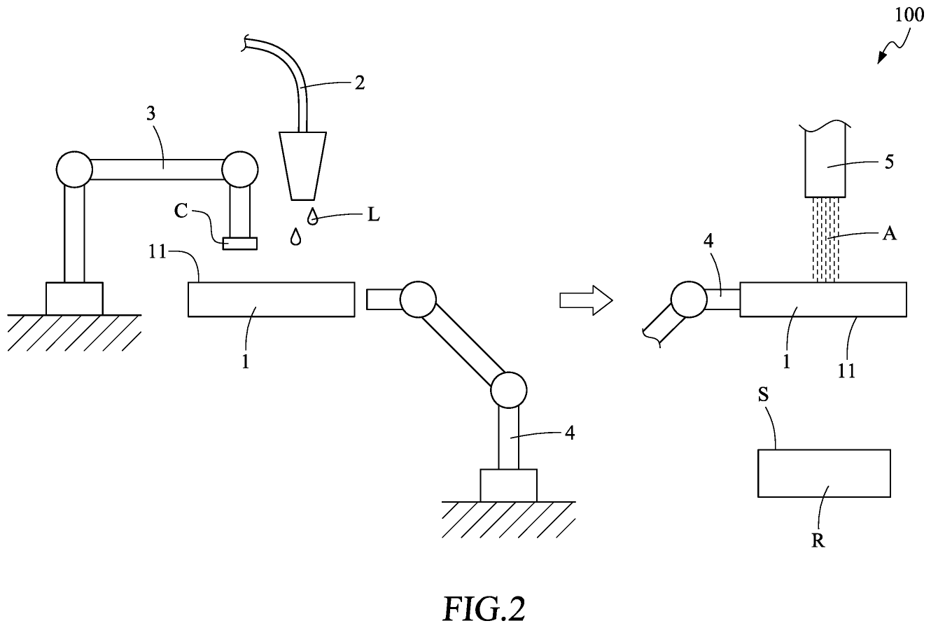

In the liquid applying step S2, shown in FIG. 1, liquid L is applied on the carrier surface 11 of the carrier substrate 1 as shown in FIGS. 2 and 4. The carrier surface 11 is hydrophilic (that is, the chip-carrier bases 13 also are hydrophilic), and the spacing grooves 12 are hydrophobic such that the liquid L is gathered on the respective chip-carrier bases 13 while being repelled by the plurality of spacing grooves 12.

As shown in FIGS. 1, 2 and 5, in the chip disposing step S3, a plurality of chips C are respectively disposed onto the plurality of chip-carrier bases 13 with the liquid L gathered on each chip-carrier base 13 being sandwiched between each chip-carrier base 13 and each chip C such that the chips C are positioned and attached on the respective chip-carrier bases 13 by surface free energy of the liquid L. In other words, the chips C can be positioned in a self-aligned manner on the respective chip-carrier bases 13.

As shown in FIGS. 1 and 2, in the carrier substrate transporting step S4, the carrier substrate 1 on which the plurality of chips are being positioned and attached are transported to a position where the carrier surface 11 of the carrier substrate 1 faces toward a receiving surface S, that is, a surface of a substrate having circuits for mounting electron elements, of a receiving substrate R, such as a substrate having circuits of an electronic device.

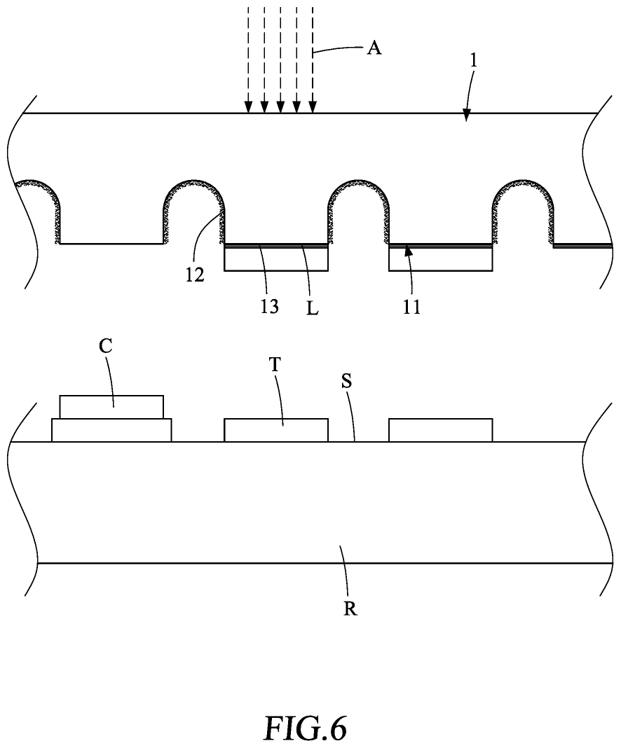

As shown in FIG. 6, in the chip transferring step S5, an electromagnetic wave A is radiated to the carrier substrate 1 so as to heat and evaporate the liquid L between each chip-carrier base 13 and each chip C such that the chips C are released from the chip-carrier bases 13 and fall down to the receiving surface S of the receiving substrate R.

As shown in FIG. 6, in the automated-position-aligning method S100 for transferring chip according to the embodiment of the present invention, a plurality of chip-receiving bases T, such as a conductive portion of a substrate having circuits, are formed on the receiving surface S of the receiving substrate R. In other words, in the carrier substrate transporting step S4, the carrier surface 11 of the carrier substrate 1 faces toward the receiving surface S of each chip-receiving base T in a manner that the chip-carrier bases 13 respectively correspond to the chip-receiving bases T on the receiving surface S such that in the chip transferring step S5, the chips C released from the chip-carrier bases 13 will correspondingly fall down to the respective chip-receiving bases T of the receiving substrate R.

Furthermore, as shown in FIGS. 1, 2 and 6, in the automated-position-aligning method S100 for transferring chip according to the embodiment of the present invention, the carrier substrate 1 is a substrate made of glass transparent to the electromagnetic wave A radiated in the chip transferring step S1 to enable the liquid L between each chip-carrier base 13 and each chip C to be radiated by the electromagnetic wave A. However, the present invention is not limited to this, and the carrier substrate 1 may be made of other transparent materials, such as PMMA (poly(methyl methacrylate)).

Moreover, as shown in FIGS. 1, 2 and 6, in the automated-position-aligning method S100 for transferring chip according to the embodiment of the present invention, the liquid L applied on the carrier surface 11 of the carrier substrate 1 is water which is evaporable by the electromagnetic wave A applied in the chip transferring step S2. However, the present invention is not limited to this, and the liquid L may be de-ionized water, alcohol, and the like.

In detail, as shown in FIGS. 1, 2 and 6, in the chip transferring step S5 of the automated-position-aligning method S100 for transferring chip according to the embodiment of the present invention, the electromagnetic wave A radiated to the carrier substrate 1 is a laser beam. However, the present invention is not limited to this, and the electromagnetic wave A may be IR (Infrared) beam and the like.

Specifically, as shown in FIG. 2, a system 100 using an automated-position-aligning method for transferring chip, which is used to implement the automated-position-aligning method S100 for transferring chip mentioned above, comprises: the carrier substrate 1, a liquid applying device 2, a chip disposing device 3, a carrier substrate transporting device 4 and a chip transferring device 5.

According to the above, as shown in FIGS. 2 and 3, the carrier substrate 1 has the carrier surface 11 and the plurality of spacing grooves 12, wherein the carrier surface 11 is hydrophilic, and all the spacing grooves 12 are hydrophobic trenches. Moreover, the carrier surface 11 is crisscrossed by the plurality of spacing grooves 12 formed thereon to form the plurality of chip-carrier bases 13, each of which is surrounded by the spacing grooves 12 intersecting with each other on the carrier surface 11 (the chip-carrier bases 13 are hydrophilic).

In detail, as shown in FIG. 3, in the carrier substrate 1 of the system 100 using the automated-position-aligning method for transferring chip according to the embodiment of the present invention, the plurality of spacing grooves 12 are a plurality of longitudinal trenches 121 arranged at lateral intervals from each other and a plurality of lateral trenches 122 arranged at longitudinal intervals from each other. Moreover, the plurality of longitudinal trenches 121 intersect the plurality of lateral trenches 122 to form the plurality of chip-carrier bases 13 in a checkerboard distribution.

Furthermore, as shown in FIGS. 2 to 4, the liquid applying device 2 is provided with a nozzle disposed corresponding to the carrier surface 11 of the carrier substrate 1. Moreover, the liquid applying device 2 is configured to apply liquid L on the carrier surface 11 of the carrier substrate 1 such that the liquid L is gathered on the respective chip-carrier bases 13 while being repelled by each trench of the plurality of spacing grooves 12.

In detail, as shown in FIGS. 2 and 5, the chip disposing device 3 is arranged corresponding to the carrier substrate 1. Moreover, the chip disposing device 3 is configured to dispose a plurality of chips C onto the plurality of chip-carrier bases 13 with the liquid L gathered on each chip-carrier base 13 being sandwiched between each chip-carrier base 13 and each chip C such that the chips C are positioned and attached in a self-aligned manner on the respective chip-carrier bases 13 by surface free energy of the liquid L.

As shown in FIGS. 2 and 6, the carrier substrate transporting device 4 is arranged corresponding to the carrier substrate 1. Moreover, the carrier substrate transporting device 4 is configured to transport the carrier substrate 1 on which the plurality of chips C are being positioned and attached to a position where the carrier surface 11 of carrier substrate 1 faces toward the receiving surface S of the receiving substrate R.

Furthermore, as shown in FIGS. 2 and 6, the chip transferring device 5 is arranged corresponding to the carrier substrate transporting device 4. Moreover, the chip transferring device 5 is configured to radiate an electromagnetic wave A to the carrier substrate 1 so as to heat and evaporate the liquid L between the plurality of chip-carrier bases 13 and the plurality of chips C such that the chips C are released from the chip-carrier bases 13 and fall down to the receiving surface S of the receiving substrate R.

Specifically, as shown in FIGS. 2 and 6, in the system 100 using the automated-position-aligning method for transferring chip according to the embodiment of the present invention, the electromagnetic wave A radiated by the chip transferring device 5 is a laser beam.

According to the above, in the present invention, the carrier surface 11 is hydrophilic (the chip-carrier bases 13 also are hydrophilic), and the spacing grooves 12 are hydrophobic such that the liquid is gathered on the respective chip-carrier bases 13. Moreover, the surface free energy of the liquid L is applied to effectively enable chips C to positional aligning on the respective chip-carrier bases 13. Furthermore, in the present invention, compared to the usage of sacrificial layer, the used of liquid L in the process of laser lift-off could greatly reduce the cost for electronic devices manufacture and solve the possible environment pollution.

The above description is merely the explanation of the preferred embodiment of the present invention. The ordinary person skilled in the art can apply other adjustments according to the claims below and the above description. However, the adjustments still belong to the technical concept of the present invention and fall into the claims of the present invention.

What is claimed is:

1. An automated-position-aligning method for transferring chip, comprising:
a chip-carrier base forming step of forming a plurality of spacing grooves on a carrier surface of a carrier substrate, wherein the carrier surface is hydrophilic, all the spacing grooves are hydrophobic trenches, and the carrier surface is crisscrossed by the plurality of spacing grooves to form a plurality of chip-carrier bases thereon, each of which is surrounded by the spacing grooves intersecting with each other;
a liquid applying step of applying liquid on the carrier surface of the carrier substrate such that the liquid is gathered on the respective chip-carrier bases while being repelled by the plurality of spacing grooves;
a chip disposing step of respectively disposing a plurality of chips onto the plurality of chip-carrier bases with the liquid gathered on each chip-carrier base being sandwiched between each chip-carrier base and each chip such that the chips are positioned and attached on the respective chip-carrier bases by surface free energy of the liquid;
a carrier substrate transporting step of transporting the carrier substrate on which the plurality of chips are being positioned and attached to a position where the carrier surface of carrier substrate faces toward a receiving surface of a receiving substrate; and
a chip transferring step of radiating an electromagnetic wave to the carrier substrate so as to heat and evaporate the liquid between each chip-carrier base and each chip such that the chips are released from the chip-carrier bases and fall down to the receiving surface of the receiving substrate.

2. The automated-position-aligning method for transferring chip as claimed in claim 1, wherein a plurality of chip-receiving bases are formed on the receiving surface of the receiving substrate, and in the carrier substrate transporting step, the carrier surface of carrier substrate faces toward the receiving surface of the receiving substrate in a manner that the chip-carrier bases respectively correspond to the chip-receiving bases on the receiving surface.

3. The automated-position-aligning method for transferring chip as claimed in claim 1, wherein in the chip-carrier base forming step, the carrier surface is subjected to a smoothing process to become hydrophilic, and the spacing groove is subjected to a roughening process to become hydrophobic.

4. The automated-position-aligning method for transferring chip as claimed in claim 1, wherein in the chip-carrier base forming step, the carrier substrate is a substrate made of glass transparent to the electromagnetic wave radiated in the chip transferring step to enable the liquid between each chip-carrier base and each chip to be radiated by the electromagnetic wave.

5. The automated-position-aligning method for transferring chip as claimed in claim 4, wherein in the liquid applying step, the liquid applied on the carrier surface of the carrier substrate is water which is evaporable by the electromagnetic wave applied in the chip transferring step.

6. The automated-position-aligning method for transferring chip as claimed in claim 1, wherein in the chip transferring step, the electromagnetic wave radiated to the carrier substrate is a laser beam.

7. The automated-position-aligning method for transferring chip as claimed in claim 1, wherein in the chip-carrier base forming step, the plurality of spacing grooves are a plurality of longitudinal trenches arranged at lateral intervals from each other, and a plurality of lateral trenches arranged at longitudinal intervals from each other, and the plurality of longitudinal trenches intersect the plurality of lateral trenches to form the plurality of chip-carrier bases in a checkerboard distribution.

8. A system using an automated-position-aligning method for transferring chip, comprising:
a carrier substrate having a carrier surface and a plurality of spacing grooves, wherein the carrier surface is hydrophilic, all the spacing grooves are hydrophobic trenches, and the carrier surface is crisscrossed by the plurality of spacing grooves formed thereon to form a plurality of chip-carrier bases, each of which is surrounded by the spacing grooves intersecting with each other on the carrier surface;
a liquid applying device provided with a nozzle disposed corresponding to the carrier surface of the carrier substrate and configured to apply liquid on the carrier surface of the carrier substrate such that the liquid is gathered on the respective chip-carrier bases while is repelled by the plurality of spacing grooves;
a chip disposing device arranged corresponding to the carrier substrate and configured to dispose a plurality of chips onto the plurality of chip-carrier bases with the liquid gathered on each chip-carrier base being sandwiched between each chip-carrier base and each chip such that the chips are positioned and attached on the respective chip-carrier bases by surface free energy of the liquid;
a carrier substrate transporting device arranged corresponding to the carrier substrate and configured to transport the carrier substrate on which the plurality of chips are being positioned and attached to a position where the carrier surface of carrier substrate faces toward a receiving surface of a receiving substrate; and
a chip transferring device arranged corresponding to the carrier substrate transporting device and configured to radiate an electromagnetic wave to the carrier substrate so as to heat and evaporate the liquid between the plurality of chip-carrier bases and the plurality of chips such that the chips are released from the chip-carrier bases and fall down to the receiving surface of the receiving substrate.

9. The system using the automated-position-aligning method for transferring chip as claimed in claim 8, wherein in the carrier substrate, the plurality of spacing grooves are a plurality of longitudinal trenches arranged at lateral intervals from each other and a plurality of lateral trenches arranged at longitudinal intervals from each other, and the plurality of longitudinal trenches intersect the plurality of lateral trenches to form the plurality of chip-carrier bases in a checkerboard distribution.

10. The system using the automated-position-aligning method for transferring chip as claimed in claim 8, wherein the electromagnetic wave radiated by the chip transferring device is a laser beam.
